(19) United States
(12) Patent Application Publication
(10) Pub. No.: US 2011/0215294 A1
(43) Pub. Date: Sep. 8, 2011

(54) SEMICONDUCTOR LIGHT EMITTING DEVICE AND METHOD OF FABRICATING THE SAME

(75) Inventors: Takeyuki SUZUKI, Kanagawa-ken (JP); Hidefumi YASUDA, Kanagawa-ken (JP); Yuko KATO, Kanagawa-ken (JP)

(73) Assignee: Kabushiki Kaisha Toshiba, Tokyo (JP)

(21) Appl. No.: 13/025,966

(22) Filed: Feb. 11, 2011

(30) Foreign Application Priority Data
Mar. 8, 2010 (JP) P2010-050322

(51) Int. Cl. H01L 33/06; H01L 33/24

(52) U.S. Cl. 257/13; 438/39; 257/E33.008; 257/E33.023; 257/E33.068

(57) ABSTRACT

According to one embodiment, a semiconductor light emitting device, including a light emission portion including a first semiconductor layer with a first conductive type, a light emission layer on the first semiconductor layer, a second semiconductor layer with a second conductive type on the light emission layer and a transparent electrode on the second semiconductor layer, and a plurality of light outlet holes inside the light emission portion, the plurality of light outlet holes communicating with the first semiconductor layer from a surface side of the transparent electrode, at least a part of light emitted from the light emission layer being extracted from the plurality of the outlet holes to outside.

### CROSS REFERENCE TO RELATED APPLICATION

This application is based upon and claims the benefit of priority from prior Japanese Patent Application No. 2010-050322, filed on Mar. 8, 2010, the entire contents of which are incorporated herein by reference.

### FIELD

Exemplary embodiments described herein generally relate to a semiconductor light emitting device and a method of fabricating the semiconductor light emitting device.

### BACKGROUND

A light emission element, a light emitting diode (LED) or the like, for example, which is used as a device in display or illumination has been desired to have a higher light emission efficiency.

External quantum efficiency is represented by product of internal quantum efficiency and external light emission efficiency and is an index which shows light emission characteristics of the light emission element. Here, external light emission efficiency shows efficiency taking out the emission light from an inner portion of a semiconductor crystal to an external side. It is said that higher external quantum efficiency leads to an element with higher light emission efficiency.

Therefore, technology increasing external light emission efficiency has been developed as an approach for improving the external quantum efficiency of the semiconductor light emission element.

A conventional technology mentioned below, for example, is disclosed for improving the external light emission efficiency. In the conventional technology, concavity and convexity is formed on a transparent conductive layer on a surface of the light emission element, for example.

However, new technology which increases both the internal quantum efficiency and the external light emission efficiency has been desired for further improvement of the external quantum efficiency of the semiconductor light emission element.

### BRIEF DESCRIPTION OF THE DRAWINGS

FIG. 1 is a schematic diagram showing a structure of a semiconductor light emission element according to a first embodiment. FIG. 1A is a plane view showing a chip plane of the semiconductor light emission element, FIG. 1B and FIG. 1C are cross-sectional views showing the semiconductor light emission element along line Ib-Ib in FIG. 1B and line Ic-Ic in FIG. 1C, respectively;

FIG. 2 is a schematic diagram illustrating effect of taking out light from the semiconductor light emission element according to the first embodiment. FIG. 2A and FIG. 2B show a semiconductor light emission element according to a comparative example and the semiconductor light emission element according to the first embodiment, respectively;

FIG. 3 is a schematic diagram showing improvement of the semiconductor light emission element on internal quantum efficiency according to the first embodiment. FIG. 3A and FIG. 3B show the semiconductor light emission elements according to the first embodiment and the comparative example, respectively;

FIG. 4 is a graph showing a relationship between external quantum efficiency of the semiconductor light emission element and an injection current density;

FIG. 5 is a cross-sectional view schematically showing a fabricating process of the semiconductor light emission element according to the first embodiment. FIG. 5A is a cross-sectional view showing a layered structure of the semiconductor light emission element and FIG. 5B, 5C are structures in which a transparent electrode is formed on a surface of the semiconductor layer, and in which a second electrode is formed on the transparent electrode, respectively;

FIG. 6 is a cross-sectional view schematically showing the fabricating process of the semiconductor light emission element successively from FIG. 5. FIG. 6A and FIG. 6B are cross-sectional views showing a structure in which a mesa groove and a plurality of light outlet holes are formed and a structure in which a first electrode is formed, respectively;

FIG. 7 is a cross-sectional view schematically showing a fabricating process according to a modification of the first embodiment. FIG. 7A and FIG. 7B are cross-sectional views showing a structure in which a transparent electrode is patterned and a structure in which a mesa groove and a plurality of light outlet holes are formed, respectively.

FIG. 8 is a schematic diagram showing semiconductor light emission elements according to a second embodiment. FIG. 8A and FIG. 8B are plane views showing chip planes of the semiconductor light emission elements according to the second embodiment and a modification of the second embodiment, respectively.

### DETAILED DESCRIPTION

According to one embodiment, a semiconductor light emitting device, including a light emission portion including a first semiconductor layer with a first conductive type, a light emission layer on the first semiconductor layer, a second semiconductor layer with a second conductive type on the light emission layer and a transparent electrode on the second semiconductor layer, and a plurality of light outlet holes inside the light emission portion, the plurality of light outlet holes communicating with the first semiconductor layer from a surface side of the transparent electrode, at least a part of light emitted from the light emission layer being extracted from the plurality of the outlet holes to outside.

According to another embodiment, a method of fabricating a semiconductor light emitting device, including forming a light emission layer on a first semiconductor layer with a first conductive type, forming a second semiconductor layer with a second conductive type on the light emission layer, forming a transparent electrode on the second semiconductor layer, simultaneously forming a mesa groove and a plurality of light outlet holes, the mesa groove penetrating into the first semiconductor layer from a surface side of the second semiconductor layer, the plurality of the light outlet holes communicating with the first semiconductor layer from a surface side of the second semiconductor layer through the second semiconductor layer and the light emission layer.

Embodiments will be described below in detail with reference to the attached drawings mentioned above.

Further, throughout the attached drawings, similar or same reference numerals show similar, equivalent or same components. The explanation in detail is suitably omitted, while a different portion is suitably explained.

The embodiments are explained as a first conductive type nitride semiconductor and a second conductive type nitride semiconductor are set to be an n-type and a p-type, respectively. However, it can be applied that the first conductive type nitride semiconductor and the second conductive type nitride semiconductor are set to be a p-type and an n-type, respectively.

### First Embodiment

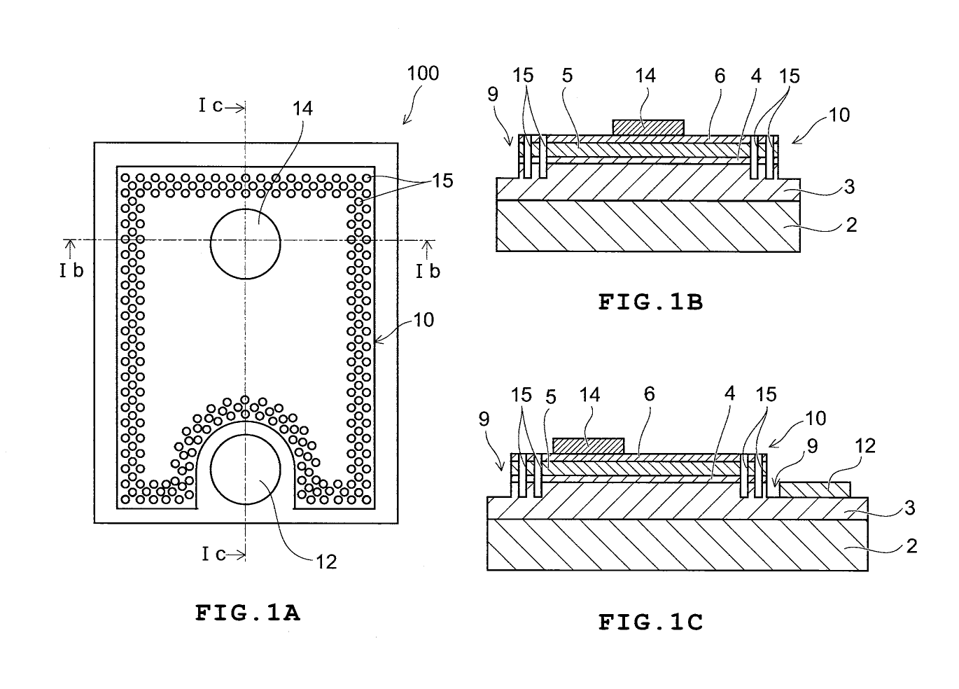

FIG. 1 is a schematic diagram showing a structure of a semiconductor light emission element according to a first embodiment. A semiconductor light emission element 100 disclosed below is a light emitting diode (LED) which is constituted with a nitride semiconductor as a material.

FIG. 1A is a plane view showing a chip plane of the semiconductor light emission element 100. FIG. 1B and FIG. 1C are cross-sectional views showing the semiconductor light emission element 100 along line Ib-Ib in FIG. 1B and line Ic-Ic in FIG. 1C, respectively

As shown in the cross-sectional views of FIG. 1B and FIG. 1C, the semiconductor light emission element 100 includes, for example, an n-type GaN layer 3 illustrated as a first semiconductor layer on a sapphire substrate 2, a light emission layer 4 on the n-type GaN layer 3, and a p-type GaN layer 5 illustrated as a second semiconductor layer on the light emission layer 4.

Further, the semiconductor light emission element 100 includes a transparent electrode 6 on the p-type GaN layer 5 and a plurality of light outlet holes 15 communicating with the n-type GaN layer 3 from a surface side of the transparent electrode 6.

A SiC substrate, a GaN substrate or the like, for example, other than the sapphire substrate 2 can be used as the substrate. A nitride semiconductor AlGaN or the like other than GaN can be used as the first semiconductor layer and the second semiconductor layer.

Further, the semiconductor light emission element 100 as shown in FIG. 1B and FIG. 1C includes a light emission portion 10 separated by a mesa groove 9. The mesa groove 9 is configured to penetrate into the n-type GaN layer from a surface side of the p-type GaN layer 5 so as to separate the p-type GaN layer 5 and the light emission layer for an adjacent light emission portion (not shown).

The transparent electrode 6 is formed on the surface of the p-type GaN layer 5. Here, the transparent electrode is a conductive layer in which emission light emitted from the light emission layer 4 can be passed through. An indium tin oxide (ITO) layer, for example, can be used as the transparent electrode.

A layered structure in which an n-type AlGaN clad layer, a multi-quantum-well (MQW) layer and a p-type AlGaN clad layer, for example, are laminated from a side of the n-type GaN layer 3 in order can be used as the light emission layer 4. The MQW layer in which an n-type GaN barrier layer being approximately 5 nm thick and an InGaN layer being approximately 2 nm are alternately laminated, for example, can be used in the light emission layer.

As shown in FIG. 1A, the light outlet holes 15 are formed along a periphery of the light emission portion 10 in the semiconductor light emission element 100. As shown in FIGS. 1B and 1C, the light outlet holes 15 are configured to penetrate into the p-type GaN layer 5 and the light emission layer 4 from a surface side of the transparent electrode 6 so as to communicate with the n-type GaN layer 3.

Further, the semiconductor light emission element 100 includes an n-side electrode 12 and a p-side electrode 14. The n-side electrode 12 illustrated as a first electrode is formed at a bottom portion of the mesa groove 9 out side the light emission portion 10 to electrically connected to the n-type GaN layer 3. The p-side electrode 14 illustrated as a second electrode is formed on the transparent electrode 6 to electrically connect each other.

Next, a sequence of actions of the semiconductor light emission element 100 is explained. The semiconductor light emission element 100 is acted by applying electrical current from the p-side electrode 14 to the n-side electrode 12 through the light emission layer 4 to emit light from the light emission layer 4. A light output emitted from the light emission portion 10 of the semiconductor light emission element 100 to an external side is dependent on amount of the electrical current passed from the p-side electrode 14 to the n-side electrode 12. The light output power is increased with increasing the injected electrical power. External quantum efficiency is an index which indicates a ratio of the light output power to the electrical power injected into the light emission element. Higher external quantum efficiency has lower power consumption so as to lead to a high efficiency light emission element.

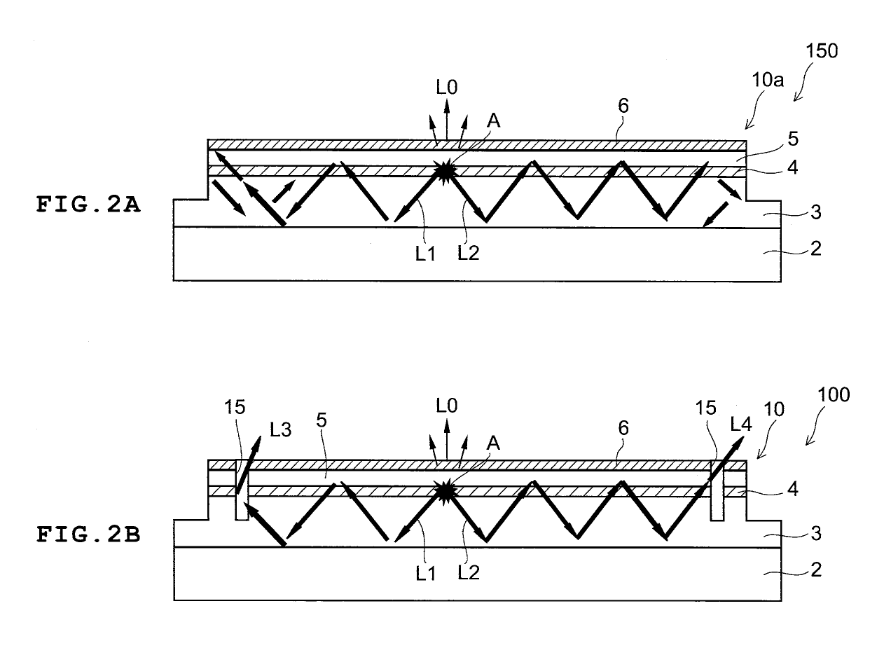

FIG. 2 is a schematic diagram illustrating effect of taking out light from the semiconductor light emission element according to the first embodiment. FIG. 2A and FIG. 2B are partial cross-sectional views showing semiconductor light emission elements of a comparative example and the semiconductor light emission element according to the first embodiment, respectively.

Light outlet holes are not configured to a light emission portion 10a in a semiconductor light emission element 150 as shown in FIG. 2A. For example, as shown in the same figure as light L₀, a part of the emission light emitted at the point A of the light emission layer 4 transmits into an upper portion. Further, the light L₀ passes through an interface between the p-type GaN layer 5 and the transparent electrode 6 so as to be emitted outside the light emission portion 10a. On the other hand, emission lights L₁, L₂ which are parts of the emission light emitted at the point A of the light emission layer 4 transmits into a lower portion, as shown by the arrows in FIG. 2A. Further, the lights L₁, L₂ are repeatedly reflected at interfaces between the sapphire substrate 2 and the n-type GaN layer 3, and between the p-type GaN layer 5 and the transparent electrode 6, respectively, so as to transmit in the light emission portion 10a.

Further, as not shown in FIG. 2A, another part of the emission light emitted at the point A transmits into the upper portion and is incident at an interface between the p-type GaN layer 5 and the transparent electrode 6 with larger incident angle than a critical angle of total reflection. As a result, another part of the emission light is reflected between the p-type GaN layer 5 and the transparent electrode 6 so as to transmit in the light emission portion 10a in repeated reflection manner.

In another part of the emission light as mentioned above, a part of the emission light is incident into the interface between the p-type GaN layer 5 and the transparent electrode 6 with a smaller angle than the critical angle of total reflection and passes through the interface between the p-type GaN layer 5 and the transparent electrode 6 so as to be emitted outside the light emission portion 10a. However, a refractive index difference between the p-type GaN layer 5 and the transparent electrode 6 is large. Accordingly, a critical angle is small, so that a ratio of the emission light outside the light emission portion 10a to the total emission light is also small.

On the other hand, the transmitting part of the emission light with repeated reflection manner in the light emission portion 10a decays by light absorption of the light emission layer 4 or light absorption in the n-type GaN layer 3 generated by free carrier or the like. Consequently, large amount of the emission light emitted from the light emission layer 4 is transformed into heat due to kinds of light absorption factors without emitting outside the light emission portion 10a.

In contrast, in a case of the semiconductor light emission element 100 as shown in FIG. 2B, the light outlet holes 15 penetrating into the n-type GaN layer 3 from the surface side of the transparent electrode 6 is formed in the light emission portion 10. As shown by arrowed lines L₃ and L₄, a part of the emission light, which transmits in the light emission portion 10 with repeated reflection manner, is incident into the light outlet hole 15 with a smaller angle than the critical angle so as to be emitted outside the light emission portion 10. Further, a part of the emission light, which is scattered in a sidewall of the light outlet holes 15, is incident into the interface between the p-type GaN layer 5 and the transparent electrode 6 with a smaller angle than the critical angle so as to be emitted outside the light emission portion 10.

Accordingly, external light emission efficiency can be improved due to the light outlet holes 15 configured to the light emission portion 10 in the semiconductor light emission element 100 according to the first embodiment. Consequently, the external quantum efficiency according to the first embodiment can be improved for that of the semiconductor light emission element 150 according to the comparative example.

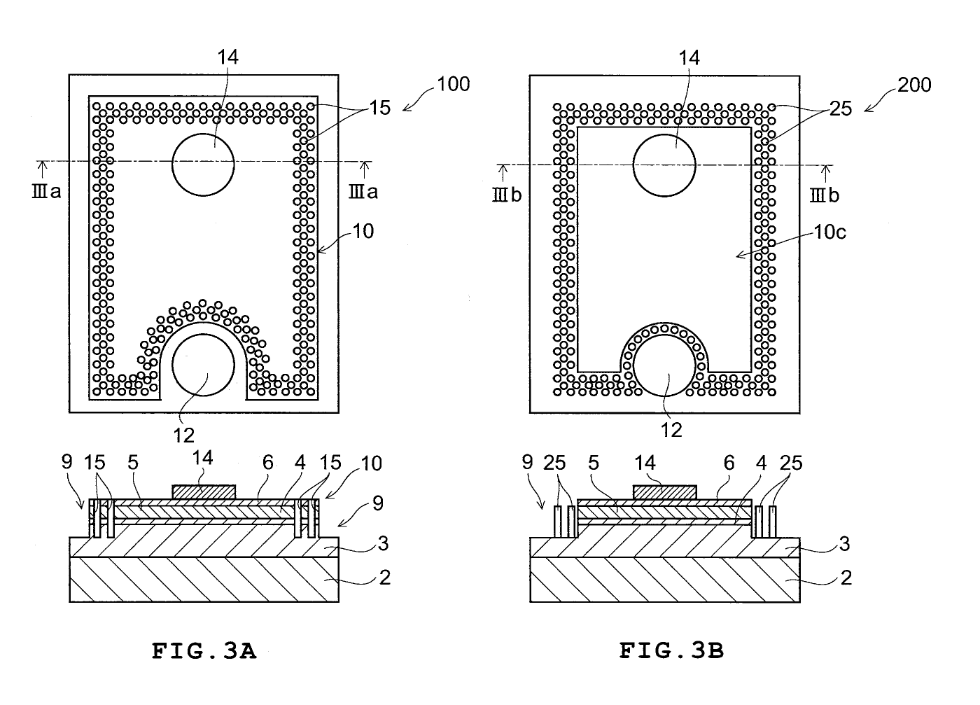

Next, FIG. 3 is a schematic diagram showing improvement of the semiconductor light emission element on internal quantum efficiency according to the first embodiment. FIG. 3A and FIG. 3B show the chip areas and cross-sectional views along line IIIa-IIIa and along line IIIb-IIIb in the semiconductor light emission elements according to the first embodiment and the comparative example, respectively.

As mentioned above, the light outlet holes 15 as shown in FIG. 3A are formed along an inner periphery of the light emission portion 10 in the semiconductor light emission element 100 to improve the external light emission efficiency. On the other hand, light scattering bodies 25, each body is like a protrusion, are formed along a periphery of a light emission portion 10c of a semiconductor light emission element 200.

The light scattering body 25 formed in the semiconductor light emission element 200 as shown in FIG. 3B play a role in emitting a part of the emission light outside the semiconductor light emission element 200. The emission light is emitted in the light emission layer 4 of the light emission portion 10c, and is repeatedly reflected in the light emission portion 10c so as to be transmitted into the n-type GaN layer 3 which is extended to the periphery of the light emission portion 10c.

Namely, the emission light, which is incident into a boundary between the light scattering body 25 and an external side from the n-type GaN layer 3 with an incident angle having a smaller angle than the critical angle of the total reflection, is emitted to the external side through the boundary between the light scattering body 25 and the external side. The light scattering body 25, for example, can be formed as a cylindrical shape. Consequently, the critical angle can be actually widened, so that a ratio of the emission light emitted outside the semiconductor light emission element can be enlarged.

In such a manner, external light emission efficiency of the semiconductor light emission element 200 can be improved due to the light scattering bodies 25 formed along the periphery of the light emission portion 10c. However, the light scattering body 25 is separated from the transparent electrode 6 formed on a surface of the light emission portion 10c. Accordingly, the light scattering body 25 cannot be passed through electrical current, so that emission light emitted from the light emission layer 4 included in the light scattering body 25 cannot be generated.

Consequently, an area of the light emission portion 10c of the semiconductor light emission element 200 as shown in FIG. 3B is smaller than that of the light emission portion 10 of the semiconductor light emission element 100 as shown in FIG. 3A. The area difference is corresponded to the periphery portion designed as the light scattering body 25. As a result, when the electrical current amount from the p-side electrode 14 to the n-side electrode 12 is the same each other, a current density injected into the light emission layer 4 of the semiconductor light emission element 200 is higher than that of the light emission layer 4 of the semiconductor light emission element 100.

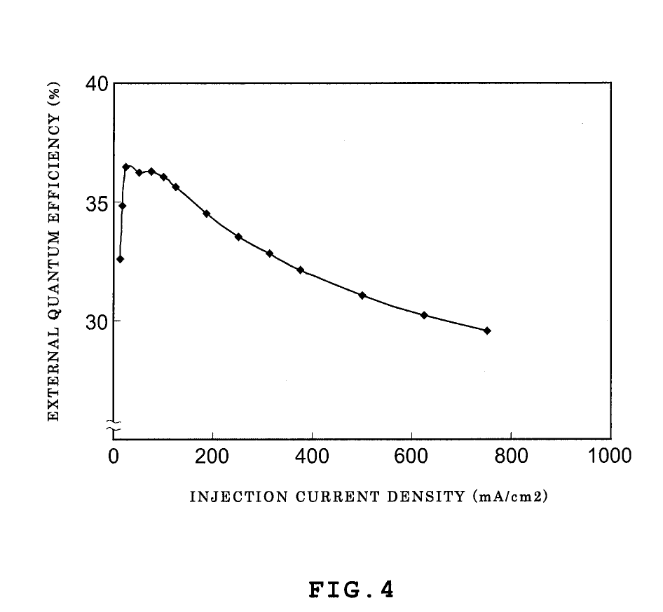

FIG. 4 is a graph showing a relationship between external quantum efficiency of the semiconductor light emission element and injection current density. The vertical axis shows external quantum efficiency and the horizontal axis shows injection current density.

As shown in FIG. 4, the external quantum efficiency is increased with increasing the injection current density in a region where the current density injected into the light emission layer 4 is low, and attains saturating point where the external quantum efficiency becomes maximum. Further, the electrical current not to contribute to emit light is increased with increasing the injection current density, so that the external quantum efficiency is decreased with increasing the injection current density.

The external light emission efficiency of the semiconductor light emission element is determined by an element structure, and is independent to the injection current density. Therefore, it can be regarded that a variation of the external quantum efficiency as shown in FIG. 4 indicates a variation of internal quantum efficiency of the semiconductor light emission element. Namely, the result indicates the internal quantum efficiency is decreased with increasing the current density in the region where the injection current density is higher than the saturating point of the external quantum efficiency.

Accordingly, the current density in the semiconductor light emission element 100 as shown in FIG. 3A becomes lower than that in the semiconductor light emission element 200 as shown in FIG. 3B, and the internal quantum efficiency is higher.

As mentioned above, both the external light emission efficiency and the internal quantum efficiency in the semiconductor light emission element 100 according to this embodiment can be increased by forming the light outlet holes 15 along the inner periphery of the light emission portion 10 as compared to that of the semiconductor light emission elements 150 and 200 as shown in the comparative example. Accordingly, a high efficiency semiconductor light emission element which improves external quantum efficiency can be realized.

Further, the light outlet holes 15 is not only formed along the inner periphery of the light emission portion 10 as the semiconductor light emission element 100, but also can be widely formed on whole area in the light emission portion 10. When a number of the light outlet holes 15 are increased, the area of the light emission portion 10 is narrowed. The narrowed area is corresponded to whole area of the light outlet holes 15. Therefore, lowering of the internal quantum efficiency owing to increase of the current density is generated. On the other hand, increase of the light outlet holes 15 provides increase of the external light emission efficiency. Namely, a layout of the light outlet holes 15, which can obtain the maximum external quantum efficiency, is adapted in considering with lowering of the internal quantum efficiency and increase of the external light emission efficiency to be enable to realize a high efficiency semiconductor light emission element.

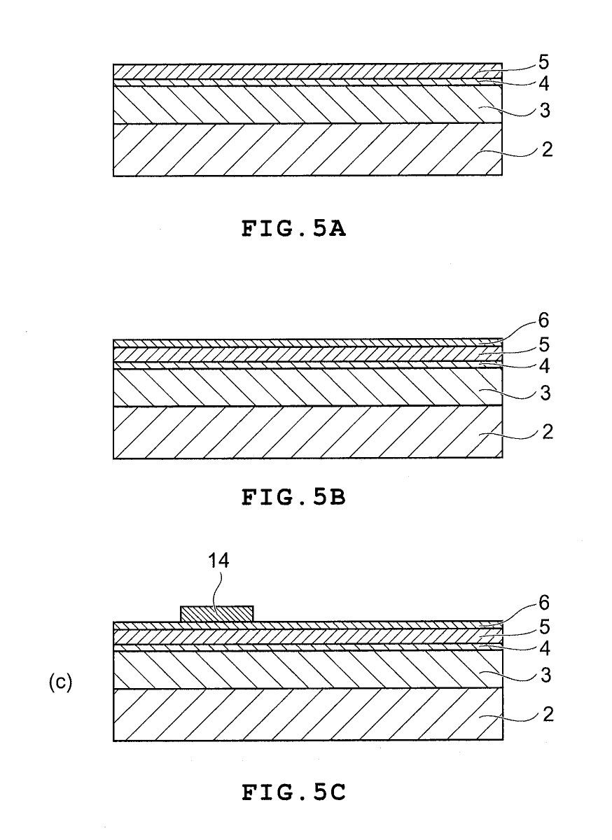

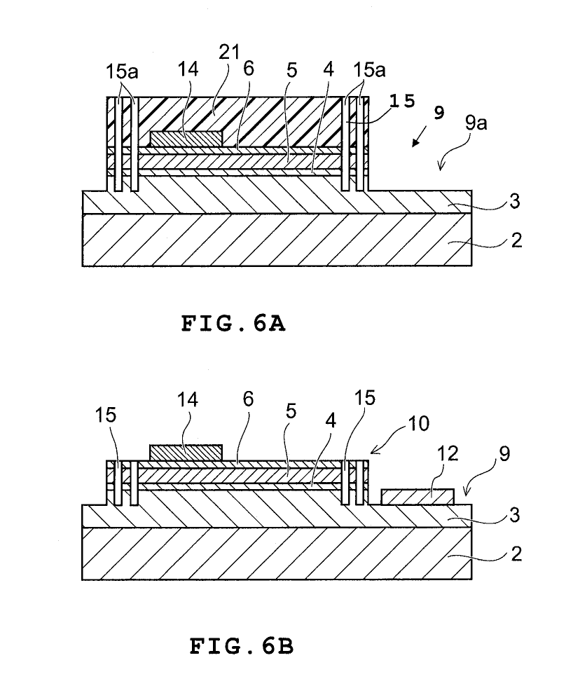

Next, a fabrication process of the semiconductor light emission element 100 is explained. FIGS. 5, 6 are cross-sectional views schematically showing the fabrication process of the semiconductor light emission element according to the first embodiment. A fabrication processes of the semiconductor light emission element 100 according to this embodiment includes the n-type GaN layer 3 used as the first semiconductor layer, the light emission layer 4 on the n-type GaN layer 3, the p-type GaN layer 5 used as the second semiconductor layer on the light emission layer 4, the transparent electrode 6 on the surface of the p-type GaN layer 5. Further, the fabrication process of the semiconductor light emission element includes the mesa groove 9 which penetrates into the n-type GaN layer 3 from the surface side of the p-type GaN layer 5 through the p-type GaN layer 5 and the light emission layer 4, and the light outlet holes 15 which communicates with the n-type GaN layer 3 from the surface side of the p-type GaN layer 5 through the p-type GaN layer 5 and the light emission layer 4.

FIG. 5A is the cross-sectional view showing a layered structure of the semiconductor light emission element 100. For example, the n-type GaN layer 3 used as the nitride semiconductor layer, the light emission layer 4 and the p-type GaN layer 5 are formed on the sapphire substrate 2 through a buffer layer (not shown).

The n-type GaN layer 3 is used as a semiconductor layer highly doped with silicon of n-type impurity nearly 10¹⁹ cm⁻³ so as to obtain low ohmic contact with the n-side electrode 12. Further, the light emission layer 4 and the p-type GaN layer 5 are layered in order on the n-type GaN layer 3. The light emission layer 4 can be formed as a layered structure with the n-type clad layer, the MQW layer and the p-type clad layer in order as mentioned above.

An AlₓGa₁₋ₓN layer (0<x<1) can be used as the n-type clad layer and the p-type clad layer. The band gap of the AlₓGa₁₋ₓN layer is wider than that of the GaN layer and can be doped with silicon or magnesium as an n-type impurity or a p-type impurity, respectively.

A layered structure n-GaN/InGaN/n-GaN/InGaN/n-GaN/InGaN,/n-AlGaN from the n-type clad layer, for example, can be used as the MQW layer. An InₓGa₁₋ₓN well layer sandwiched with an n-type GaN layers as a barrier layer can be formed as an undoped layer. A desirable light emission wave length can be obtained by controlling a component X of the InₓGa₁₋ₓN well layer and a width of the well layer.

The p-type GaN layer 5 is used as a semiconductor layer highly doped with magnesium of p-type impurity nearly 10¹⁹ cm⁻³ so as to obtain low ohmic contact with the transparent electrode 6.

The nitride semiconductor layer mentioned above can be formed by metal organic chemical vapor deposition (MOCVD), for example, using an organic metal as a source material.

Next, as shown in FIG. 5B, the transparent electrode 6 is formed on a surface of the p-type GaN layer 5. The transparent electrode 6 is a conductive layer which is transparent for emission light emitted from the light emission layer 4, for example, ITO can be used as the material. The ITO film can be formed by sputtering or evaporation.

Successively, as shown in FIG. 5C, the p-side electrode 14 used as the second electrode is formed on the transparent electrode 6. A metal film laminated with a nickel film and a gold film in order can be used as the p-side electrode 14, for example. The metal film can be formed, for example, by evaporation, and can be selectively formed on the transparent electrode 6 using patterning technology as liftoff technique or the like.

Next, as shown in FIG. 6A, an etching mask 21 which has openings 9a and 15a are formed on an area formed the mesa groove 9 and the light outlet holes 15 of surfaces of the transparent electrode 6 and the p-side electrode 14. Successively, the nitride semiconductor layer is etched by using reactive ion etching (RIE). In RIE, for example, an etching gas including chlorine (Cl₂) can be used. A resist mask can be used as the etching mask. Etching by RIE is performed from the surface of the transparent electrode 6 into a depth of the n-type GaN layer 3. In such a manner, the mesa groove 9 separating the light emission portion 10 and the light outlet holes 15 can be simultaneously formed.

Successively, as shown in FIG. 6B, the n-side electrode 12 used as the first electrode is formed on the surface of the n-type GaN layer 3 exposed at a bottom of the mesa groove 9. A metal film laminated Ti/Al/Ti/Au from the surface side of the n-type GaN layer 3 in order can be used as the n-side electrode 12, for example. The layered structure of Ti/Al/Ti/Au, for example, can be formed by sputtering, and a prescribed pattern can be formed by liftoff technique.

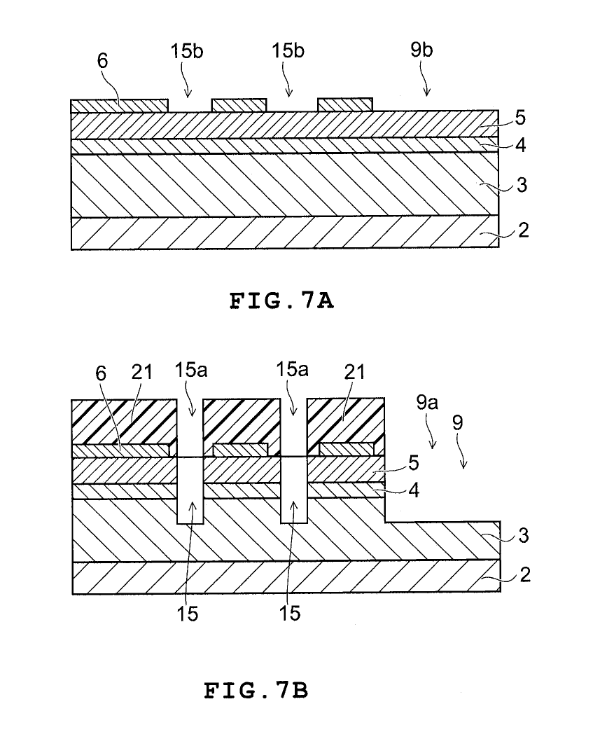

FIG. 7 is a cross-sectional view schematically showing a fabrication process of the semiconductor light emission element 100 according to a modification of the first embodiment. In the modification, preliminarily removing an area in the transparent electrode 6, in which the mesa groove 9 and the light outlet holes 15 are formed, is included in the fabrication process.

FIG. 7A is a partial cross-sectional view showing a state in which the transparent electrode 6 on the p-type GaN layer is patterned prior to being etched as shown in FIG. 6A. The transparent electrode 6 on which an area 9b including a portion of the mesa groove 9 and an area 15b including a portion of the light outlet holes 15 are etched. In etching the transparent electrode 6, for example, wet etching technique using a prescribed etching solution which is suited to a material of the transparent electrode 6 can be used. A resist mask can be formed to selectively etch the area 9b and the area 15b.

Successively, as shown in FIG. 7B, the etching mask 21 including openings corresponding to the mesa groove 9 and the light outlet holes 15 is formed. Further, the p-type GaN layer 5, the light emission layer 4, and a part of the n-type GaN layer 3 are etched, for example, by RIE using an etching gas including Cl₂ so as to form the mesa groove 9 and the light outlet hole 15. The resist mask can be used as an etching mask 21, for example.

In etching process by RIE as shown in FIG. 6A, for example, a conductive component of the transparent electrode 6 may adhere to a sidewall of the mesa groove 9 or a sidewall of the light outlet hole 15. As a result, leakage current via the sidewall passes in the semiconductor light emission element 100, so that the external quantum efficiency may be lowered.

In the modification of the fabrication process as shown in FIG. 7, the transparent electrode 6 is preliminary etched to eliminate. In such a manner, adhesion of the conductive component of the transparent electrode 6 onto the sidewalls of the mesa groove 9 and the light outlet hole 15 can be prevented. Consequently, leakage current via the sidewalls of the mesa groove 9 and the light outlet hole 15 can be suppressed to prevent lowering of the external quantum efficiency.

### Second Embodiment

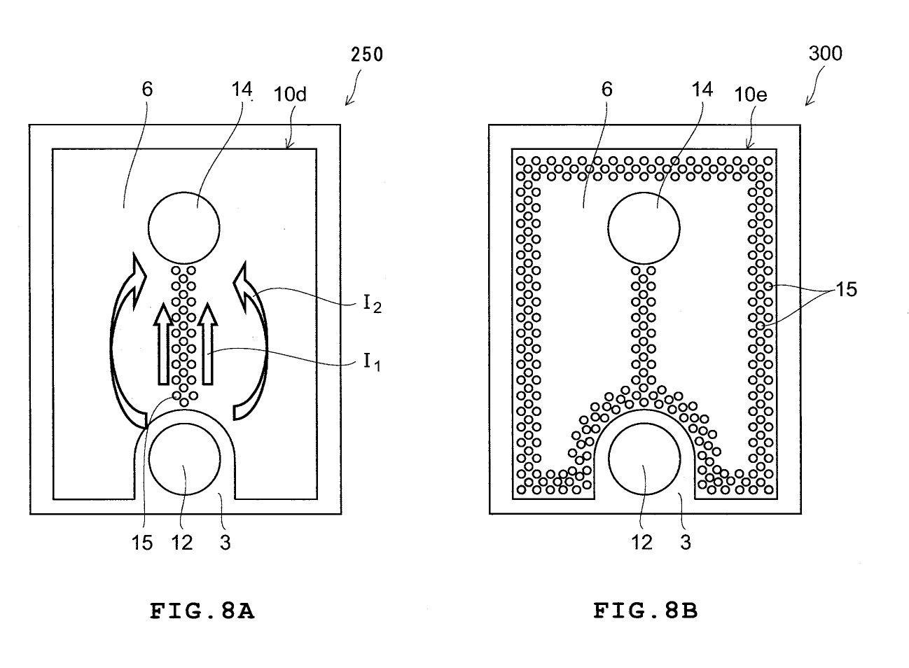

FIG. 8 is a schematic diagram showing semiconductor light emission elements according to the second embodiment. FIG. 8A and FIG. 8B are plane views showing chip planes of the semiconductor light emission elements according to the second embodiment and a modification of the second embodiment, respectively.

A light emission portion 10d of a semiconductor light emission element 250 and a light emission portion 10e of a semiconductor light emission element 300 include the transparent electrode 6, the p-type GaN layer 5, the light emission layer 4 and the n-type GaN layer 3 in common with the semiconductor light emission element 100 as shown in FIG. 1. On the other hand, each layout of light outlet holes 15 of the two semiconductor light emission elements in the second embodiment is different from the layout of the semiconductor light emission element in the first embodiment.

As shown in FIG. 8A, the semiconductor light emission element 250 includes the n-side electrode 12 formed outside the light emission portion 10d and electrically connected to the n-type GaN layer, and the p-side electrode 14 electrically connected to the transparent electrode 6. Electrical current passes from the p-side electrode 14 to the n-side electrode 12 through the transparent electrode 6, p-type GaN layer, the light emission layer 4 and the n-type GaN layer 3.

On the other hand, the plurality of the light outlet holes 15 formed in the light emission portion 10d are arranged along a current path I₁ which has the shortest electric line of force in length between the p-side electrode 14 and the n-side electrode 12. In other words, the light outlet holes 15 are arranged along the current path I₁ which has the smallest resistance between the p-side electrode 14 and the n-side electrode 12, when no light outlet holes 15 are arranged.

The resistance of the current path in the light outlet hole 15 can be the increased by arranging the current path along the p-side electrode 14 and the n-side electrode 12, as the transparent electrode 6, the p-type GaN layer 5, the light emission layer 4 and a part of the n-type GaN layer 3 are etched in the light outlet hole 15.

Consequently, the light outlet holes 15 are arranged along the current path I₁ which has the smallest resistance between the p-side electrode 14 and the n-side electrode 12 in a case without light outlet holes 15 as shown in FIG. 8A, so that electrical current passing between the p-side electrode 14 and the n-side electrode 12 can be dispersed to current path I₂ having higher resistance. In such a manner, a light emission strength distribution of the light emission layer 4 can be uniformed. Namely, concentrated electrical current in the current path I₁, where the light outlet holes 15 are arranged, are relaxed to enable to decrease injection current density. Accordingly, internal quantum efficiency can be increased. Further, external light emission efficiency of an area where the light outlet holes 15 are arranged is improved.

In the semiconductor light emission element 300 as shown in FIG. 8B, the light outlet holes 15 are arranged along an inner periphery of the light emission portion 10e in addition to the current path which has the shortest electric line of force between the p-side electrode 14 and the n-side electrode 12. Consequently, the light emission strength in the light emission portion 10e can be uniformed to have an effect of improving external light emission efficiency of the inner periphery portion, in addition to improving internal quantum efficiency. In such a manner, external quantum efficiency of the semiconductor light emission element 300 can be further improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

Furthermore, the nitride semiconductor in the embodiments includes all of semiconductor layers which represented by a chemical formula of BₓIn_{y}Al_{z}Ga_{1-x-y-z}N (0≦x≦1, 0≦y≦1, 0≦z≦1, 0<x+y+z≦1), where composition ratio x, y and z can be changed in the determined range described above. Further, in the chemical formula, the nitride semiconductor includes semiconductor layers having elements in V-group other than nitrogen and all sorts of impurity materials which are doped as controlling a conductive type or the like.

What is claimed is:

1. A semiconductor light emitting device, comprising:
a light emission portion comprising
a first semiconductor layer with a first conductive type,
a light emission layer on the first semiconductor layer,
a second semiconductor layer with a second conductive type on the light emission layer and
a transparent electrode on the second semiconductor layer; and
a plurality of light outlet holes inside the light emission portion, the plurality of light outlet holes communicating with the first semiconductor layer from a surface side of the transparent electrode, at least a part of light emitted from the light emission layer being extracted from the plurality of the outlet holes to outside.

2. The device of claim 1, wherein
the plurality of the light outlet holes are arranged along a periphery of the light emission portion.

3. The device of claim 1, further comprising:
a first electrode formed outside the light emission portion and electrically connected to the first semiconductor layer; and
a second electrode connected to the transparent electrode, the second electrode passing electrical current to the first electrode through the transparent electrode, the second semiconductor layer, the light emission layer and the first semiconductor layer.

4. The device of claim 3, wherein
the first electrode is separated from the light emission portion by a mesa groove.

5. The device of claim 4, wherein
the transparent electrode is formed inside a surface area of the second semiconductor layer separated by the mesa groove.

6. The device of claim 1, wherein
the plurality of the light outlet holes are arranged along an electrical current path which has the shortest electric line of force in length between the first electrode and the second electrode.

7. The device of claim 1, wherein
the plurality of the light outlet holes are arranged in whole of the light emission portion.

8. The device of claim 1, wherein
at least one of the first semiconductor layer and the second semiconductor layer is constituted with a nitride semiconductor.

9. The device of claim 8, wherein
the nitride semiconductor is constituted with GaN.

10. The device of claim 8,
wherein the nitride semiconductor is constituted with BₓIn_{y}Al_{z}Ga_{1-x-y-z}N (0≦x≦1, 0≦y≦1, 0≦z≦1, 0<x+y+z≦1).

11. The device of claim 1, wherein
the light emission layer is formed as a layered structure in which an AlGaN clad layer, a multi-quantum-well layer and an AlGaN clad layer are laminated in order.

12. The device of claim 11, wherein
the multi-quantum-well layer formed as a layered structure in which an n-type GaN layer and an InGaN layer are alternately laminated in order.

13. The device of claim 12, wherein
thicknesses of the n-type GaN layer and the InGaN layer are 2 nm and 5 nm, respectively, in the Multi-Quantum-Well layer.

14. The device of claim 1, further comprising:
a substrate on which the first semiconductor layer is formed.

15. The device of claim 14, wherein
a material of the substrate is at least one of sapphire, SiC and GaN.

16. The device of claim 14, further comprising:
a buffer layer formed between the substrate and the first semiconductor layer.

17. A method of fabricating a semiconductor light emitting device, comprising:
forming a light emission layer on a first semiconductor layer with a first conductive type;
forming a second semiconductor layer with a second conductive type on the light emission layer;
forming a transparent electrode on the second semiconductor layer;
simultaneously forming a mesa groove and a plurality of light outlet holes, the mesa groove penetrating into the first semiconductor layer from a surface side of the second semiconductor layer, the plurality of the light outlet holes communicating with the first semiconductor layer from a surface side of the second semiconductor layer through the second semiconductor layer and the light emission layer.

18. The method of claim 17, further comprising:
preliminarily removing an area of the transparent electrode in which the mesa groove and the plurality of the light outlet hole is formed.

19. The method of claim 17, further comprising:
forming a first electrode on the transparent electrode.

20. The method of claim 17, further comprising:
forming a second electrode on the first semiconductor layer on which the mesa groove is formed.
